(19) United States
(12) Patent Application Publication
(10) Pub. No.: US 2024/0171136 A1
(43) Pub. Date: May 23, 2024

(54) AMPLIFIER ASSEMBLY WITH REDUCED GAIN VARIATION, FRONT-END MODULE, AND MOBILE DEVICE INCLUDING THE SAME

(71) Applicant: Skyworks Solutions, Inc., Irvine, CA (US)

(72) Inventors: Anuranjan Hosagavi Puttaraju, Aliso Viego, CA (US); Hyeong Tae Jeong, Westlake Village, CA (US); Hareesh Reddy Basireddy, Cedar Rapids, IA (US)

(21) Appl. No.: 18/512,649

(22) Filed: Nov. 17, 2023

Related U.S. Application Data
(60) Provisional application No. 63/427,764, filed on Nov. 23, 2022.

(51) Int. Cl. H03F 3/19; H04B 1/40

(52) U.S. Cl. CPC H03F 3/19; H04B 1/40; H03F 2200/451

(57) ABSTRACT

A device may include an amplifying transistor configured to amplify a radio frequency signal when powered by a supply signal and biased by a biasing signal. The device may include a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

### INCORPORATION BY REFERENCE TO ANY PRIORITY APPLICATIONS

This application claims priority to U.S. Provisional Application No. 63/427,764, filed on Nov. 23, 2022 and titled “AMPLIFIER ASSEMBLY WITH REDUCED GAIN VARIATION, FRONT END MODULE, AND MOBILE DEVICE INCLUDING THE SAME,” the disclosure of which is hereby incorporated by reference in its entirety for all purposes. Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to power amplifiers for use in radio frequency (RF) electronics.

### Description of the Related Technology

Power amplifiers are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

The systems, methods and devices of this disclosure each have several innovative aspects, no single one of which is solely responsible for all of the desirable attributes disclosed herein. Details of one or more implementations of the subject matter described in this specification are set forth in the accompanying drawings and the description below.

In some aspects, the techniques described herein relate to an amplifier assembly including: an amplifying transistor configured to amplify a radio frequency signal when powered by a supply signal and biased by a biasing signal; and a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

In some aspects, the techniques described herein relate to an amplifier assembly wherein the biasing circuit is configured to increase a gain of the amplifying transistor when the level of the supply signal decreases by increasing a reference current flowing through the reference transistor.

In some aspects, the techniques described herein relate to an amplifier assembly wherein the biasing circuit includes an input node configured to receive an input current dependent on the level of the supply signal, an output node connected to the amplifying transistor to provide the biasing signal.

In some aspects, the techniques described herein relate to an amplifier assembly wherein the biasing circuit further includes a diode disposed between the reference transistor and the input node.

In some aspects, the techniques described herein relate to an amplifier assembly wherein the biasing circuit further includes an additional transistor disposed between the output node and the input node.

In some aspects, the techniques described herein relate to an amplifier assembly wherein the input node is connected to a current source dependent on the level of the supply signal.

In some aspects, the techniques described herein relate to an amplifier assembly wherein the input node is connected to a constant current source and a current leakage circuit configured to draw a leakage current from the constant current source depending on the level of the supply signal.

In some aspects, the techniques described herein relate to an amplifier assembly wherein the amplifier assembly includes multiple stages of amplifiers, and the amplifying transistor is disposed at a first stage of the amplifier assembly.

In some aspects, the techniques described herein relate to a radio frequency module including: a packaging board configured to receive a plurality of components; and an amplifier assembly implemented on the packaging board, the amplifier assembly including an amplifying transistor configured to amplify a radio frequency signal when powered by a supply signal and biased by a biasing signal, and a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

In some aspects, the techniques described herein relate to a radio frequency module wherein the radio frequency module is a front-end module.

In some aspects, the techniques described herein relate to a radio frequency module wherein the biasing circuit is configured to increase a gain of the amplifying transistor when the level of the supply signal decreases by increasing a reference current flowing through the reference transistor.

In some aspects, the techniques described herein relate to a radio frequency module wherein the biasing circuit includes an input node configured to receive an input current dependent on the level of the supply signal, an output node connected to the amplifying transistor to provide the biasing signal.

In some aspects, the techniques described herein relate to a radio frequency module wherein the biasing circuit further includes a diode disposed between the reference transistor and the input node.

In some aspects, the techniques described herein relate to a radio frequency module wherein the biasing circuit further includes an additional transistor disposed between the output node and the input node.

In some aspects, the techniques described herein relate to a radio frequency module wherein the input node is connected to a current source dependent on the level of the supply signal.

In some aspects, the techniques described herein relate to a radio frequency module wherein the input node is connected to a constant current source and a current leakage circuit configured to draw a leakage current from the constant current source depending on the level of the supply signal.

In some aspects, the techniques described herein relate to a radio frequency module wherein the amplifier assembly includes multiple stages of amplifiers, and the amplifying transistor is disposed at a first stage of the amplifier assembly.

In some aspects, the techniques described herein relate to a radio frequency module wherein the amplifier assembly includes a multistage amplifier, and the amplifying transistor is disposed at a first stage of the multistage amplifier.

In some aspects, the techniques described herein relate to a mobile device including: a transceiver configured to generate a radio frequency signal; and a front-end system including an amplifier assembly configured to amplify the radio frequency signal, the amplifier assembly including an amplifying transistor configured to amplify a radio frequency signal when powered by a supply signal and biased by a biasing signal, and a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

In some aspects, the techniques described herein relate to a mobile device wherein the biasing circuit is configured to increase a gain of the amplifying transistor when the level of the supply signal decreases by increasing a reference current flowing through the reference transistor.

In some aspects, the techniques described herein relate to a mobile device wherein the biasing circuit includes an input node configured to receive an input current dependent on the level of the supply signal, an output node connected to the amplifying transistor to provide the biasing signal.

In some aspects, the techniques described herein relate to a mobile device wherein the biasing circuit further includes a diode disposed between the reference transistor and the input node.

In some aspects, the techniques described herein relate to a mobile device wherein the biasing circuit further includes an additional transistor disposed between the output node and the input node.

In some aspects, the techniques described herein relate to a mobile device wherein the input node is connected to a current source dependent on the level of the supply signal.

In some aspects, the techniques described herein relate to a mobile device wherein the input node is connected to a constant current source and a current leakage circuit configured to draw a leakage current from the constant current source depending on the level of the supply signal.

In some aspects, the techniques described herein relate to a mobile device wherein the amplifier assembly includes multiple stages of amplifiers, and the amplifying transistor is disposed at a first stage of the amplifier assembly.

### BRIEF DESCRIPTION OF THE DRAWINGS

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 3 is a schematic diagram of one embodiment of a mobile device.

FIG. 4 is a schematic diagram of power amplifier system.

FIG. 5 is a schematic diagram of procedures of compensating the gain variation throughout multiple stages of the amplifier assembly.

FIG. 6 illustrates a schematic diagram of amplifier assembly according to certain embodiments of the present disclosure.

FIG. 7 illustrates a schematic diagram of amplifier assembly according to certain embodiments of the present disclosure.

FIGS. 8A-8C illustrates simulations of measuring the gain variation of the power assembly according to certain embodiments of the present disclosure.

FIGS. 9A-9B illustrates simulations of measuring the gain variation of the power assembly according to certain embodiments of the present disclosure.

FIG. 10A is a schematic diagram of one embodiment of a packaged module.

FIG. 10B is a schematic diagram of a cross-section of the packaged module of FIG. 10A taken along the lines 10B-10B.

FIG. 11 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

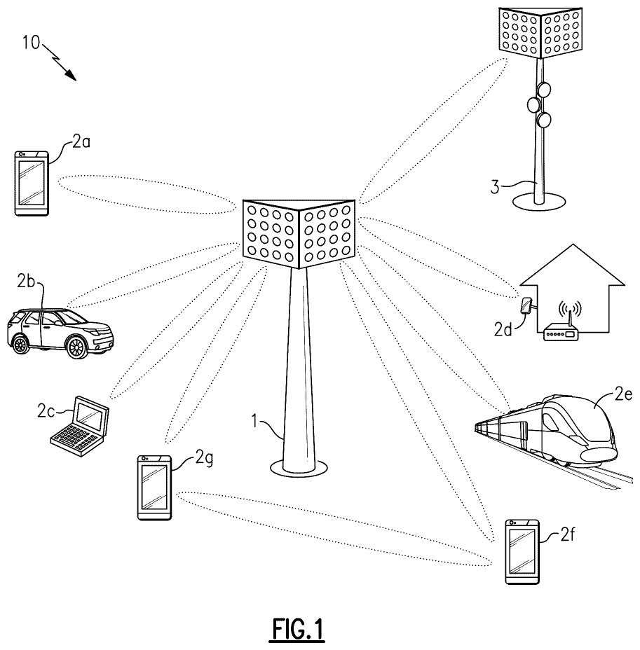

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 30 can be implemented to support self-fronthaul and/or self-backhaul (for instance, as between mobile device 32g and mobile device 32f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHZ. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHZ to 30 GHz, or more particularly, 24 GHz to 30 GHZ.

Different users of the communication network 30 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (cMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 30 of FIG. 1 can be used to support a wide variety of advanced communication features, including, but not limited to, eMBB, uRLLC, and/or mMTC.

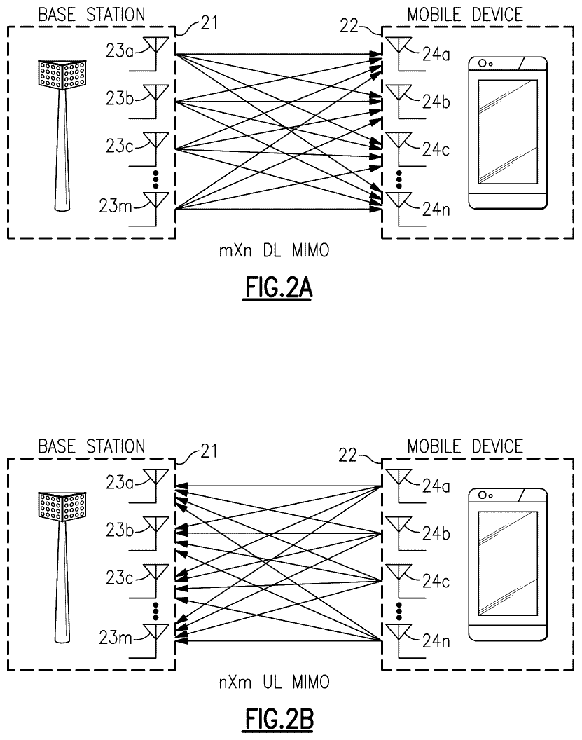

FIG. 2A is a schematic diagram of one example of a downlink channel using multi-input and multi-output (MIMO) communications. FIG. 2B is a schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 2A, downlink MIMO communications are provided by transmitting using M antennas 23a, 23b, 23c, . . . 23m of the base station 21 and receiving using N antennas 24a, 24b, 24c, . . . 24 n of the mobile device 22. Accordingly, FIG. 2A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 24a, 24b, 24c, . . . 24n of the mobile device 42 and receiving using M antennas 23a, 23b, 23c, . . . 23m of the base station 21. Accordingly, FIG. 2B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

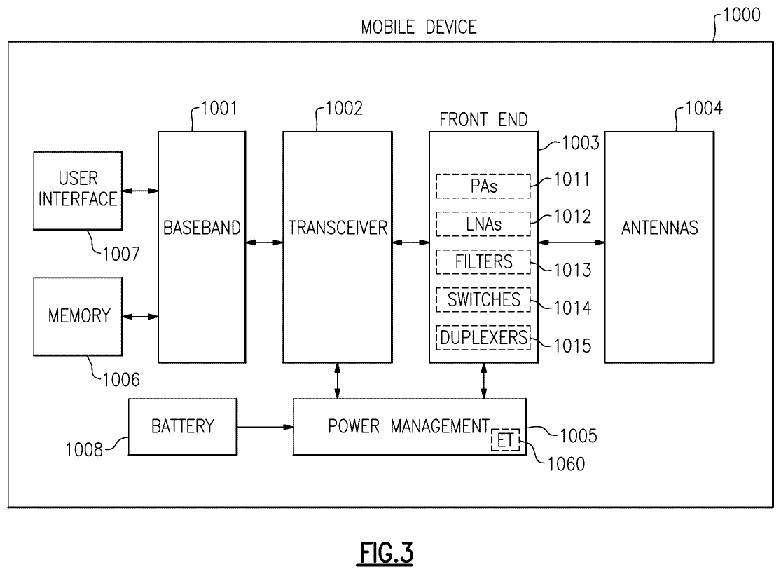

FIG. 3 is a schematic diagram of one example of a mobile device 1000. The mobile device 1000 includes a baseband system 1001, a transceiver 1002, a front-end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and receiving of RF signals can be achieved by one or more components that are collectively represented in FIG. 3 as the transceiver 1002. In one example, separate components (for instance, separate circuits or dies) can be provided for handling certain types of RF signals.

The front-end system 1003 aids in conditioning signals transmitted to and/or received from the antennas 1004. In the illustrated embodiment, the front-end system 1003 includes power amplifiers (PAs) 1011, low noise amplifiers (LNAs) 1012, filters 1013, switches 1014, and duplexers 1015. However, other implementations are possible.

For example, the front-end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front-end system 1003 can include phase shifters having variable phase controlled by the transceiver 1002. Additionally, the phase shifters are controlled to provide beam formation and directivity for transmission and/or reception of signals using the antennas 1004. For example, in the context of signal transmission, the phases of the transmit signals provided to the antennas 1004 are controlled such that radiated signals from the antennas 1004 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 3, the baseband system 1001 is coupled to the memory 1006 of facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 3 includes an envelope tracker 1060. As shown in FIG. 3, the power management system 1005 receives a battery voltage from the battery 1008. The battery 1008 can be any suitable battery for use in the mobile device 1000, including, for example, a lithium-ion battery.

The mobile device 1000 of FIG. 3 illustrates one example of an RF communication system that can include power amplifier(s) implemented in accordance with one or more features of the present disclosure. However, the teachings herein are applicable to RF communication systems implemented in a wide variety of ways.

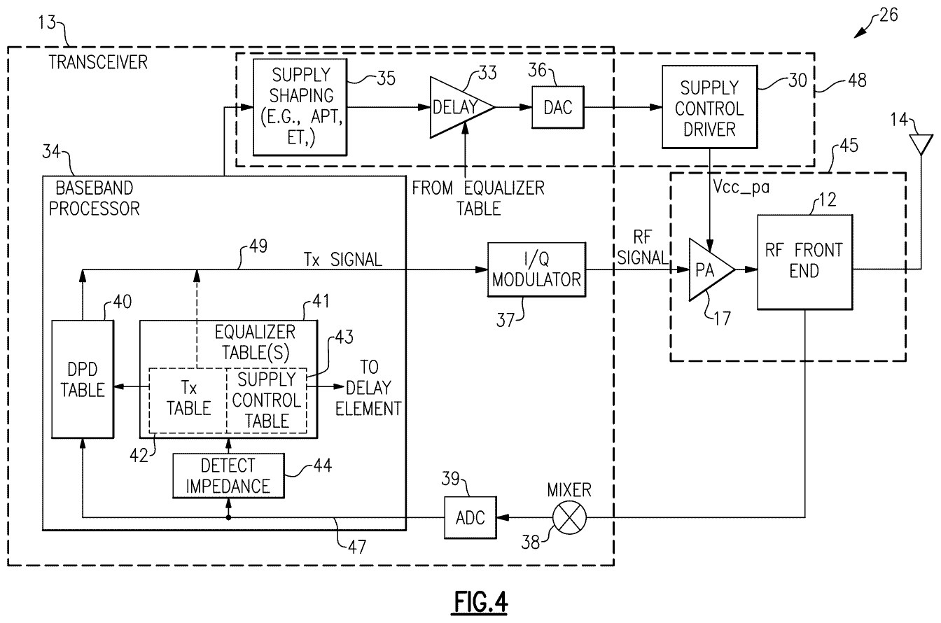

FIG. 4 is a detailed block diagram of one example of a power amplifier system 26. For example, the power amplifier system 26 may be incorporated into the mobile device 1000. The illustrated power amplifier system 26 includes an RF front-end 12, an antenna 14, a battery 21, a supply control driver 30, a power amplifier 17, and a transceiver 13. The illustrated transceiver 13 includes a baseband processor 34, a supplying shaping block or circuit 35, a delay component 33, a digital-to-analog converter (DAC) 36, a quadrature (I/Q) modulator 37, a mixer 38, and an analog-to-digital converter (ADC) 39. The supply shaping block 35, delay component 33, DAC 36, and supply control driver 30 together form a supply shaping branch 48.

The baseband processor 34 can be used to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature component of the sinusoidal wave, which can be an equivalent representation of the sinusoidal wave. In certain implementations, the I and Q signals can be provided to the I/Q modulator 37 in a digital format. The baseband processor 34 can be any suitable processor configured to process a baseband signal. For instance, the baseband processor 34 can include a digital signal processor, a microprocessor, a programmable core, or any combination thereof. Moreover, in some implementations, two or more baseband processors 34 can be included in the power amplifier system 26.

The I/Q modulator 37 can be configured to receive the I and Q signals from the baseband processor 34 and to process the I and Q signals to generate an RF signal. For example, the I/Q modulator 37 can include DACs configured to convert the I and Q signals into an analog format, mixers for upconverting the I and Q signals to radio frequency, and a signal combiner for combining the upconverted I and Q signals into an RF signal suitable for amplification by the power amplifier 17. In certain implementations, the I/Q modulator 37 can include one or more filters configured to filter frequency content of signals processed therein.

The supply shaping block 35 can be used to convert an envelope or amplitude signal associated with the I and Q signals into a shaped power supply control signal, such as an average power tracking (APT) signal or an envelope tracking (ET) signal, depending on the embodiment. Shaping the envelope signal from the baseband processor 34 can aid in enhancing performance of the power amplifier system 26. In certain implementations, such as where the supplying shaping block is configured to implement an envelope tracking function, the supply shaping block 35 is a digital circuit configured to generate a digital shaped envelope signal, and the DAC 36 is used to convert the digital shaped envelope signal into an analog shaped envelope signal suitable for use by the supply control driver 30. However, in other implementations, the DAC 36 can be omitted in favor of providing the supply control driver 30 with a digital envelope signal to aid the supply control driver 30 in further processing of the envelope signal.

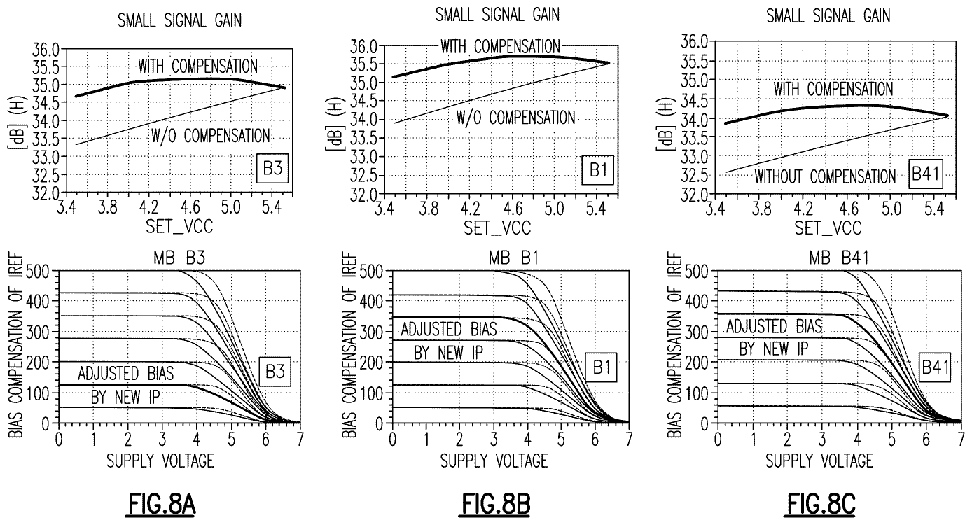

The supply control driver 30 can receive the supply control signal (e.g., an analog shaped envelope signal or APT signal) from the transceiver 13 and a battery voltage VBATT from the battery 21, and can use the supply control signal to generate a power amplifier supply voltage VCC_PA for the power amplifier 17 that changes in relation to the transmit signal. The power amplifier 17 can receive the RF transmit signal from the I/Q modulator 37 of the transceiver 13, and can provide an amplified RF signal to the antenna 14 through the RF front-end 12. In other cases, a fixed power amplifier supply voltage VCC_PA is provided to the power amplifier 17. In some such embodiments, one or more of the supply shaping block 35, DAC 36, and supply control driver 30 may not be included. Exemplary waveforms of power amplifier supply voltage VCC_PA and corresponding RF transmit signals are shown in FIGS. 8A, 8B, and 8C for fixed supply, APT, and ET power supply control operations, respectively. In some embodiments, the power amplifier system 26 is capable of performing two or more supply control techniques. For instance, the power amplifier system 26 allows for selection (e.g., via firmware programming or other appropriate mechanism) of two or more of ET, APT, and fixed power supply control modes. In such cases, the baseband processor or other appropriate controller or processor may instruct the supply shaping block 35 to enter into the appropriate selected mode.

The delay component 33 implements a selectable delay in the supply control path. As will be described in further detail, this can be useful in some cases for compensating for non-linearities and/or other potential sources of signal degradation. The illustrated delay component is shown in the digital domain as part of the transceiver 13, and may comprise a FIFO or other type of memory-based delay element. However, the delay component 33 can be implemented in any appropriate fashion, and in other embodiments may be integrated as part of the supply shaping block 35, or may be implemented in the analog domain, after the DAC 36, for example.

The RF front-end 12 receives the output of the power amplifier 17, and can include a variety of components including one or more duplexers, switches (e.g., formed in an antenna switch module), directional couplers, and the like.

The directional coupler (not shown) within the RF front-end 12 can be a dual directional coupler or other appropriate coupler or other device capable of providing a sensed output signal to the mixer 38. According to certain embodiments, including the illustrated embodiment, the directional coupler is capable of providing both incident and reflected signals (e.g., forward and reverse power) to the mixer 38. For instance, the directional coupler can have at least four ports, which may include an input port configured to receive signals generated by the power amplifier 17, an output port coupled to the antenna 14, a first measurement port configured to provide forward power to the mixer 38, and a second measurement port configured to provide reverse power to the mixer 38.

The mixer 38 can multiply the sensed output signal by a reference signal of a controlled frequency (not illustrated in FIG. 4) so as to downshift the frequency spectrum of the sensed output signal. The downshifted signal can be provided to the ADC 39, which can convert the downshifted signal to a feedback signal 47 in a digital format suitable for processing by the baseband processor 34. As will be discussed in further detail, by including a feedback path between the output of the power amplifier 17 and an input of the baseband processor 34, the baseband processor 34 can be configured to dynamically adjust the I and Q signals and/or power control signal associated with the I and Q signals to optimize the operation of the power amplifier system 26. For example, configuring the power amplifier system 26 in this manner can aid in controlling the power added efficiency (PAE) and/or linearity of the power amplifier 32. The mixer 38, ADC 39 and/or other appropriate componentry may generally perform a quadrature (I/Q) demodulation function in some embodiments.

Although the power amplifier system 26 is illustrated as include a single power amplifier, the teachings herein are applicable to power amplifier systems including multiple power amplifiers, including, for example, multi-mode and/or multi-mode power amplifier systems.

Additionally, although FIG. 4 illustrates a particular configuration of a transceiver, other configurations are possible, including for example, configurations in which the transceiver 13 includes more or fewer components and/or a different arrangement of components.

As shown the baseband processor 34 can include a digital pre-distortion (DPD) table 40, an equalizer table 41, and a complex impedance detector 44. The DPT table 40 may be stored in a non-volatile memory (e.g., flash memory, read only memory (ROM), etc.) of the transceiver 34 that is accessible by the baseband processor 34. According to some embodiments, the baseband processor 34 accesses entries in the DPD table 40 to aid in linearizing the power amplifier 17. For instance, the baseband processor 34 selects appropriate entries in the DPD table 40 based on the sensed feedback signal 47, and adjusts the transmit signal accordingly, prior to outputting the transmit signal to the I/Q modulator 37. For example, DPD can be used to compensate for certain nonlinear effects of the power amplifier 17, including, for example, signal constellation distortion and/or signal spectrum spreading. According to certain embodiments including the illustrated embodiment, the DPD table 40 implements memoryless DPD, e.g., where the current output of the DPD corrected transmit signal depends only on the current input.

ET technique is one of the most suitable solutions when considering both linearity and efficiency. The ET technique improves the efficiency by modulating the drain voltage of the PA according to the envelope of the input signal. Meanwhile, an average power tracking (APT) is also a widely-implemented approach to reduce unnecessary power consumption in RF PAs. Despite of various advantages of ET technique, such as improved linearity, APT technique still has its own advantage in terms of efficiency of the power amplifier system in particular when it comes with a low output voltage. The APT offers fine results for low output power and ET improves efficiency at high output power and high PAPR. Thus, it would be beneficial to selectively determine a voltage supplying mode (ATP or ET) for the power amplifier system based on the level of output power.

Various techniques adjust supply Vcc in order to improve the efficiency of the power amplifier. The most popular techniques in modern communication are Envelope Tracking (ET) and Average Power Tracking (APT) which are widely used as efficiency enhancement method of 5G communication system in both base station and handset application. However, a power amplifier circuit will have gain variation over voltage due to the base to collector parasitic capacitance of the various PA stages which is a function of the base-collector voltage of the transistor.

For an APT system, the large gain variation over voltage requires complicated power calibration algorithm of handset application. APT calibration in the factory always deviates from the ideal APT table because PA small signal Gain droop at low Vcc/Icq is not compensated during calibration. For example, if at some mid power level the PA gain droops 2 dB, APT voltage/Icq would be 2 dB higher than desired. Usually this is not a big problem at maximum power because Vcc is not much below the 5.5V maximum, and therefore the gain drop is small. However, in the 16 dBm range, this could be a problem.

Hereinafter, am amplifier assembly with reduced gain variation according to certain embodiments of the present disclosure to address the problems described above is presented. The proposed solution involves adding a voltage variable bias scheme to the PA. More specifically, the PA bias is controlled as a function of voltage. An example of the solution may include steps of (1) detecting supply voltage variation and (2) adjusting bias to maintain constant gain of power amplifiers.

FIG. 5 is a schematic diagram of procedures of compensating the gain variation throughout multiple stages of the amplifier assembly.

The amplifier assembly may include multiple stages of PAs, and the gain of the first stage of the PAs can be adapted to compensate the gain variation of the whole amplifier assembly. As shown in FIG. 5, the gain of the whole amplifier assembly has been improved.

The embodiments of the present disclosure may be adopted to any stage of PAs if it has a multi-stage assembly. But it can be most effective to use for a first stage PA bias since its compensation has little effect on other performance such as linearity and PAE.

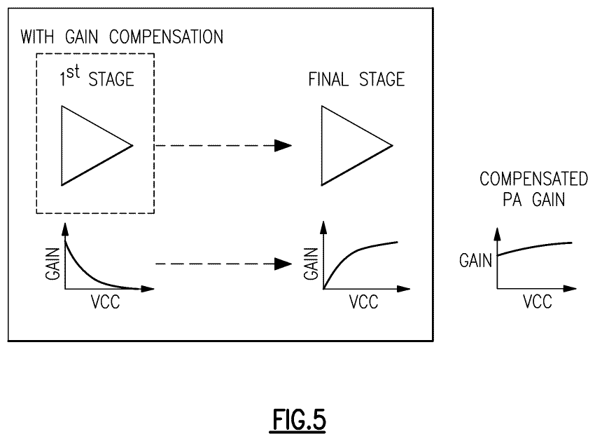

FIG. 6 illustrates a schematic diagram of an amplifier assembly 600 according to certain embodiments of the present disclosure. The amplifier assembly 600 according to certain embodiments of the present disclosure includes an amplifying transistor 602 and a biasing circuit 604. According to certain embodiments, the amplifier assembly 600 may include multiple stages of amplifiers, and the amplifying transistor 602 is disposed at a first stage of the amplifier assembly 600. In some implementations, the amplifier assembly 600 may include a multistage amplifier and the amplifying transistor 602 may be disposed at a first stage of the multistage amplifier. The amplifier assembly 600 according to the present disclosure may be applied to an ET system or an APT system.

The amplifying transistor 602 is configured to amplify a radio frequency signal when powered by a supply signal (Vcc) and biased by a biasing signal. The amplifying transistor 602 may be a bipolar junction transistor (BJT) including a base, a collector, and an emitter. The amplifying transistor 602 may be powered by the supply signal through the collector, and biased by the biasing signal through the base which is connected to an output node 610 of the biasing circuit 604. The emitter of the amplifying transistor 602 may be connected to ground.

The biasing circuit 604 is configured to control the biasing signal based on a level of the supply signal. More specifically, the biasing circuit 604 may be configured to adjust the biasing signal depending on a variation of the supply signal to compensate a gain variation of the amplifier assembly. To that end, the amplifier assembly may further include a detecting circuit (not shown) configured to detect a level of the supply signal.

The biasing circuit 604 may include a reference transistor 606 which is mirrored with the amplifying transistor 602 to control a current (Ic) flowing through the amplifying transistor 602 such as to compensate a gain variation of the amplifier assembly 600. The reference transistor 606 may be a bipolar junction transistor (BJT) having a base, a collector, and an emitter. The current (Ic) of the amplifying transistor 602 may be a collector current flowing into the collector of the amplifying transistor 602. The reference transistor 606 and the amplifying transistor 602 may include a current mirror, and therefore a reference current (Iref) flowing into the collector of the reference transistor 606 may be associated with the collector current (Ic) of the amplifying transistor 602. More specifically, the biasing circuit 604 may be configured to increase the reference current (Iref) flowing through the reference transistor 606 to increase a collector current (Ic) of the amplifying transistor 602. Alternatively, the biasing circuit 604 may be configured to decrease the reference current (Iref) flowing through the reference transistor 606 to decrease a collector current (Ic) of the amplifying transistor 602.

According to certain embodiments of the present disclosure, the biasing circuit 604 may be configured to increase a gain of the amplifying transistor 602 when the level of the supply signal decreases, by increasing a reference current (Iref) flowing through the reference transistor 606. Alternatively, the biasing circuit 604 may be configured to decrease a gain of the amplifying transistor 602 when the level of the supply signal increases, by decreasing a reference current (Iref) flowing through the reference transistor 606.

The biasing circuit 604 may include an input node 608 configured to receive an input current dependent on the level of the supply signal (Vcc). For example, as the level of the supply signal decreases, the input current may be increased. In addition, as the level of the supply signal increases, the input current may be decreased. The input node 608 may be connected to a diode 612 and an additional transistor 614. The diode 612 may be connected to a base of the reference transistor 606 through a resistor 618. The input node 608 may be connected to a base of the additional transistor 614. The additional transistor 614 may be a bipolar junction transistor (BJT) having a base a collector, and an emitter, and powered by DC voltage (VBATT) through its collector.

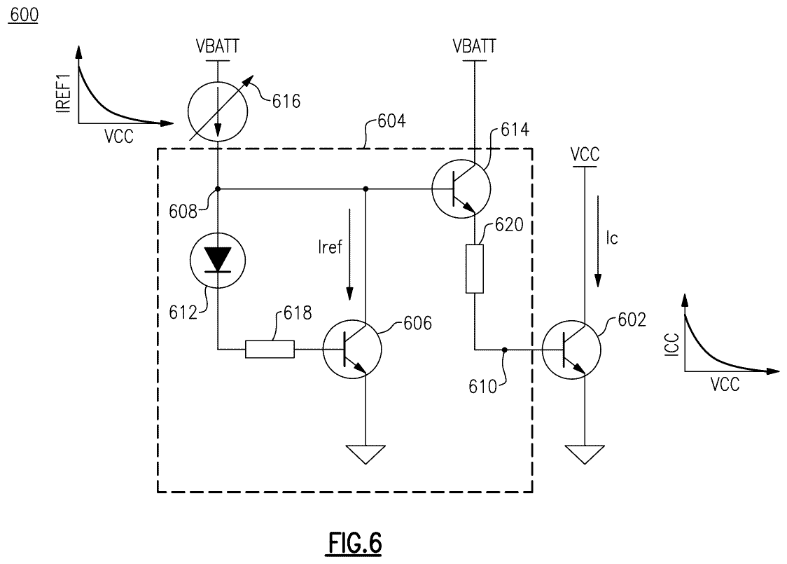

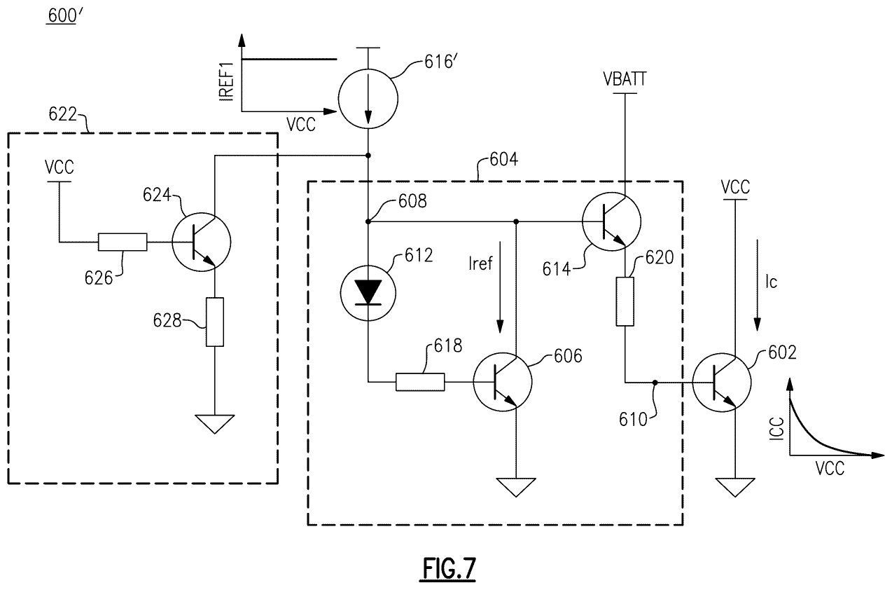

According to certain embodiments, the input node 608 may be connected to a current source 616 dependent on the supply signal. The current source 616 may be powered by DC voltage (VBATT). However, the way of providing the input current to the input node is not limited thereto. For example, it is also possible to adopt a constant current source, and this example will be described referring to FIG. 7.

The biasing circuit 604 may include an output node 610 connected to the amplifying transistor 602 to provide the biasing signal. More specifically, the output node 601 may be connected to the base of the amplifying transistor 602. Also, the output node 610 may be connected to the additional transistor 614 via a resistor 620. More specifically, the resistor 620 is connected to an emitter of the additional transistor 614.

The biasing circuit may include the diode 612 disposed between the reference transistor 606 and the input node 608. The biasing circuit may further include the additional transistor 614 disposed between the output node 610 and the input node 608.

The amplifier assembly 600 shown in FIG. 6 may be implemented on a complementary metal-oxide semiconductor (CMOS) die.

FIG. 7 illustrates a schematic diagram of amplifier assembly 600′ according to certain embodiments of the present disclosure. The difference between the amplifier assembly 600 of FIG. 6 and the amplifier assembly 600′ is that the amplifier assembly 600′ further includes the current leakage circuit 622 and the current source connected to the input node 608 is a constant current source 616′. Apart from that, configurations of the amplifier assembly 600′ may be identical or functionally similar to that of the amplifier assembly 600.

As already mentioned, the amplifier assembly 600′ may further include the current leakage circuit 622. The current leakage circuit 622 may be configured to draw a leakage current from the constant current source 616′ depending on the level of the supply signal. For example, as the level of the supply signal decreases, the current leakage circuit 622 may reduce an amount of the leakage current. Therefore, the reference current (Iref) will increase and subsequently the current (Ic) of the amplifying transistor 602 will increase as well.

According to certain embodiments, the current leakage circuit 622 may include a leakage transistor 624. The leakage transistor 624 may be a bipolar transistor (BJT) having a base, a collector, and an emitter. The current leakage circuit 622 may further include a resistor 626 connected to the base of the leakage transistor 624. The base of the leakage transistor 624 may be connected to a supply power providing the supply signal (Vcc) via the resistor 626. The current leakage circuit 622 may further include a resistor 628 connected between the emitter of the leakage transistor 624 and a ground.

The amplifier assembly 600′ shown in FIG. 7 may be implemented on a heterojunction bipolar transistor (HBT) die.

FIGS. 8A, 8B and 8C illustrate simulations of measuring the gain variation of the power assembly according to certain embodiments of the present disclosure.

Referring to the simulations of FIGS. 8A, 8B and 8C, the gain variation of the amplifier assembly according to the present invention (indicated as ‘with compensation’) is significantly improved in comparison with a conventional implementation (indicated as ‘without compensation’).

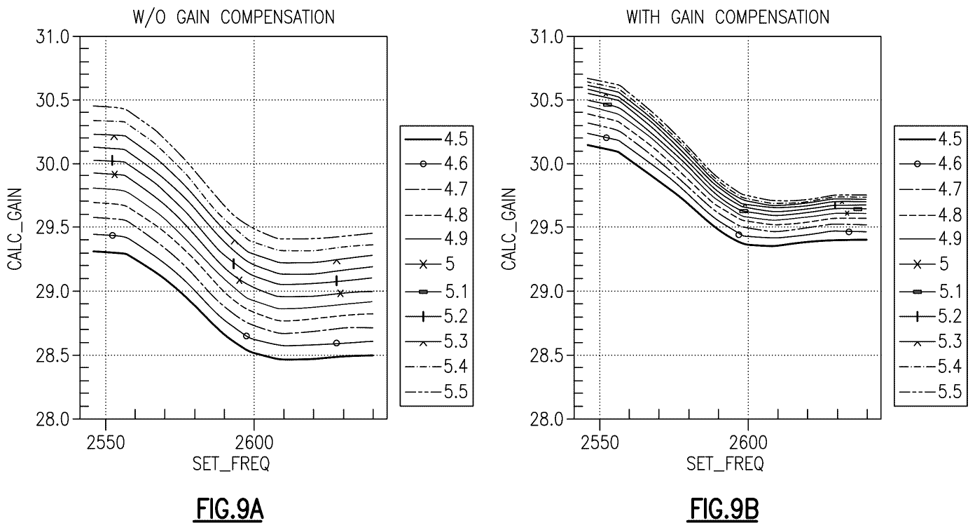

FIGS. 9A, 9B illustrate simulations of measuring the gain variation of the power assembly according to certain embodiments of the present disclosure.

Referring to FIGS. 9A, 9B, the gain variation of the amplifier assembly according to the present invention is significantly improved in terms of variation of level of supply signal (for example, 4.5V to 5.5V).

Previous solutions require more calibration and complexity due to wide PA gain variation over voltage. This also places an extra burden on the transceiver to deliver high power into the PA at lower voltages (e.g., the PA has lower gain at lower voltage).

This solution can minimize the gain variation over voltage and prevents the linearity degradation by mobile phone APT look-up table (LUT) calibration algorithm.

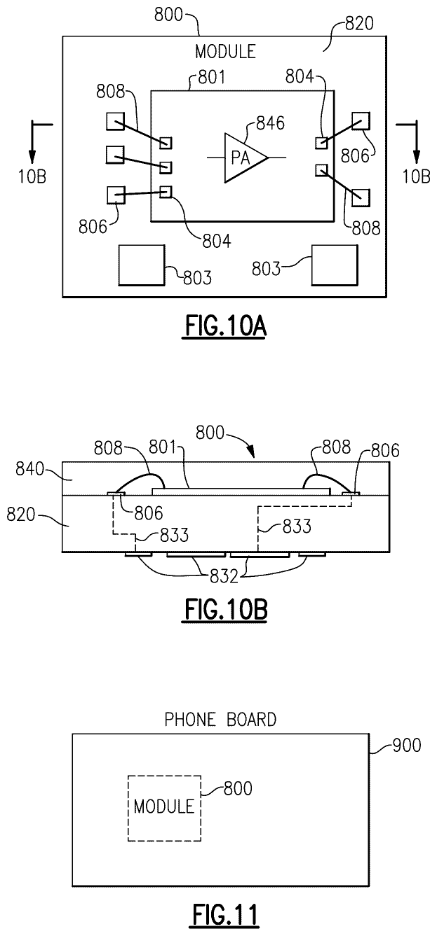

FIG. 10A is a schematic diagram of one embodiment of a packaged module 800. FIG. 10B is a schematic diagram of a cross-section of the packaged module 800 of FIG. 10A taken along the lines 10B-10B.

The packaged module 800 includes an IC or die 801, surface mount components 803, wirebonds 808, a package substrate 820, and encapsulation structure 840. The package substrate 820 includes pads 806 formed from conductors disposed therein. Additionally, the die 801 includes pads 804, and the wirebonds 808 have been used to electrically connect the pads 804 of the die 801 to the pads 806 of the package substrate 820.

The die 801 includes a power amplifier system 846, which can be implemented in accordance with any of the embodiments herein.

The packaging substrate 820 can be configured to receive a plurality of components such as the die 801 and the surface mount components 803, which can include, for example, surface mount capacitors and/or inductors.

As shown in FIG. 10B, the packaged module 800 is shown to include a plurality of contact pads 832 disposed on the side of the packaged module 800 opposite the side used to mount the die 801. Configuring the packaged module 800 in this manner can aid in connecting the packaged module 800 to a circuit board such as a phone board of a wireless device. The example contact pads 832 can be configured to provide RF signals, bias signals, power low voltage(s) and/or power high voltage(s) to the die 801 and/or the surface mount components 803. As shown in FIG. 10B, the electrical connections between the contact pads 832 and the die 801 can be facilitated by connections 833 through the package substrate 820. The connections 833 can represent electrical paths formed through the package substrate 820, such as connections associated with vias and conductors of a multilayer laminated package substrate.

In some embodiments, the packaged module 800 can also include one or more packaging structures to, for example, provide protection and/or facilitate handling of the packaged module 800. Such a packaging structure can include overmold or encapsulation structure 840 formed over the packaging substrate 820 and the components and die(s) disposed thereon.

It will be understood that although the packaged module 800 is described in the context of electrical connections based on wirebonds, one or more features of the present disclosure can also be implemented in other packaging configurations, including, for example, flip-chip configurations.

FIG. 11 is a schematic diagram of one embodiment of a phone board 900. The phone board 900 includes the module 800 shown in FIGS. 10B-10B attached thereto. Although not illustrated in FIG. 11 for clarity, the phone board 900 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such amplifier assemblies can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might.” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An amplifier assembly comprising:
an amplifying transistor configured to amplify a radio frequency signal when powered by a supply signal and biased by a biasing signal; and
a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

2. The amplifier assembly of claim 1 wherein the biasing circuit is further configured to increase a gain of the amplifying transistor when the level of the supply signal decreases by increasing a reference current flowing through the reference transistor.

3. The amplifier assembly of claim 1 wherein the biasing circuit includes an input node configured to receive an input current dependent on the level of the supply signal and an output node connected to the amplifying transistor to provide the biasing signal.

4. The amplifier assembly of claim 3 wherein the biasing circuit further includes a diode disposed between the reference transistor and the input node.

5. The amplifier assembly of claim 3 wherein the biasing circuit further includes an additional transistor disposed between the output node and the input node.

6. The amplifier assembly of claim 3 wherein the input node is connected to a current source dependent on the level of the supply signal.

7. The amplifier assembly of claim 3 wherein the input node is connected to a constant current source and a current leakage circuit configured to draw a leakage current from the constant current source depending on the level of the supply signal.

8. The amplifier assembly of claim 1 further comprising multiple stages of amplifiers, and the amplifying transistor is disposed at a first stage of the amplifier assembly.

9. A radio frequency module comprising:
a packaging board configured to receive a plurality of components; and
an amplifier assembly implemented on the packaging board, the amplifier assembly including an amplifying transistor configured to amplify a radio frequency signal when powered by a supply signal and biased by a biasing signal, and a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

10. The radio frequency module of claim 9 wherein the radio frequency module is a front-end module.

11. The radio frequency module of claim 9 wherein the biasing circuit is further configured to increase a gain of the amplifying transistor when the level of the supply signal decreases by increasing a reference current flowing through the reference transistor.

12. The radio frequency module of claim 9 wherein the biasing circuit includes an input node configured to receive an input current dependent on the level of the supply signal and an output node connected to the amplifying transistor to provide the biasing signal.

13. The radio frequency module of claim 12 wherein the biasing circuit further includes a diode disposed between the reference transistor and the input node.

14. The radio frequency module of claim 12 wherein the biasing circuit further includes an additional transistor disposed between the output node and the input node.

15. The radio frequency module of claim 12 wherein the input node is connected to a current source dependent on the level of the supply signal.

16. The radio frequency module of claim 12 wherein the input node is connected to a constant current source and a current leakage circuit configured to draw a leakage current from the constant current source depending on the level of the supply signal.

17. The radio frequency module of claim 9 wherein the amplifier assembly includes a multistage amplifier, and the amplifying transistor is disposed at a first stage of the multistage amplifier.

18. A mobile device comprising:
a transceiver configured to generate a radio frequency signal; and
a front-end system including an amplifier assembly configured to amplify the radio frequency signal, the amplifier assembly including an amplifying transistor configured to amplify a radio frequency signal when powered by a supply signal and biased by a biasing signal, and a biasing circuit configured to control the biasing signal based on a level of the supply signal, the biasing circuit including a reference transistor which is mirrored with the amplifying transistor to control a current flowing through the amplifying transistor such as to compensate a gain variation of the amplifier assembly.

19. The mobile device of claim 18 wherein the biasing circuit is configured to increase a gain of the amplifying transistor when the level of the supply signal decreases by increasing a reference current flowing through the reference transistor.

20. The mobile device of claim 18 wherein the biasing circuit further includes a diode disposed between the reference transistor and an input node configured to receive an input current dependent on the level of the supply signal.
